(19) United States
(12) Patent Application Publication
(10) Pub. No.: US 2004/0150947 A1
(43) Pub. Date: Aug. 5, 2004

(54) Technique for controlling rotational vibration related to a drive module

(76) Inventor: Kenneth K. Tang, Sacramento, CA (US)

Correspondence Address: HEWLETT-PACKARD COMPANY, Intellectual Property Administration, P.O. Box 272400, Fort Collins, CO, 80527-2400, US

(21) Appl. No.: 10/355,796

(22) Filed: Jan. 31, 2003

(51) Int. Cl. H05K 5/00

(52) U.S. Cl. 361/685

(57) ABSTRACT

A system for controlling rotational vibration. The system comprises a device chassis and at least one module with a rotating component. The module is slidably mounted in the device chassis via a pair of guide rails formed of a magnesium material.

### BACKGROUND OF THE INVENTION

Rotational vibration can be induced in a variety of systems by components that utilize rotatable parts. For example, disk drives, such as disk drives used in high performance storage array products, often create rotational vibrations. The rotational vibrations can inhibit system performance by, for example, slowing read/write operations of the disk drives.

As the data density and data access performance from each generation of disk drives increases, the detrimental impact of rotational vibrations also increases. Attempts have been made to limit the effects of rotational vibration by adding polymer and foam grommets to isolate transmission of vibration to the surrounding device chassis; by creating a heavy disk drive carrier; by increasing external chassis stiffness via rigid structural disk bays; or by incorporating rotational vibration control springs at the carrier to disk bay interfaces. However, each of these approaches is undesirable due to factors, such as complexity, cost, increased part counts and excess weight.

### SUMMARY

In one embodiment of the present invention, a disk drive system is provided. The system comprises a disk drive and a carrier in which the disk drive is affixed. The carrier has a structural member comprising magnesium to stiffen the carrier and control rotational vibration.

In another embodiment, a system is provided for controlling rotational vibration. The system utilizes a device chassis and a plurality of disk drive modules. Each disk drive module is mounted in the device chassis by a pair of guide rails. The guide rails are formed of a magnesium material.

In another embodiment, a method is provided for reducing rotational vibration associated with a disk drive. The method comprises forming a pair of structural members from a magnesium-based material. The method further comprises attaching the pair of structural members to a disk drive. The disk drive is then mounted in a chassis.

### BRIEF DESCRIPTION OF THE DRAWINGS

Certain embodiments of the invention will hereafter be described with reference to the accompanying drawings, wherein like reference numerals denote like elements, and:

FIG. 1 is a perspective view of an electronic device utilizing at least one drive module according to an embodiment of the present invention;

FIG. 2 is a front perspective view of one of the drive modules illustrated in FIG. 1 according to an embodiment of the present invention;

FIG. 3 is a perspective view of an embodiment of the guide frame used with the drive module illustrated in FIG. 2 according to an embodiment of the present invention;

FIG. 4 is a perspective view of an embodiment of the external side of the guide rails illustrated in FIG. 3 according to an embodiment of the present invention; and

FIG. 5 is a perspective view of the inside of the guide rails illustrated in FIG. 3 according to an embodiment of the present invention.

### DETAILED DESCRIPTION

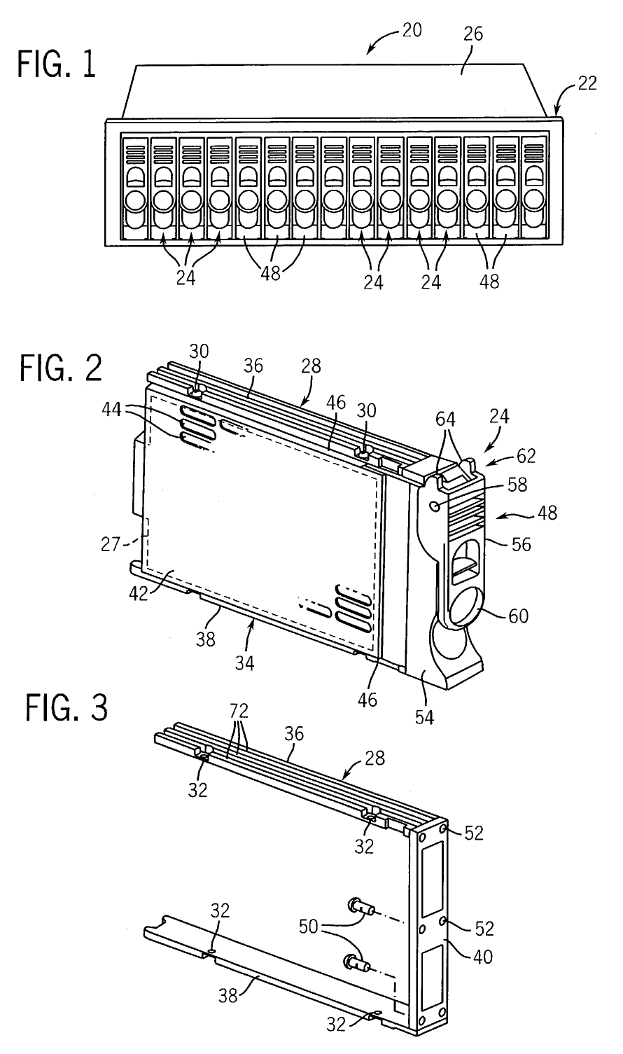

Referring generally to FIG. 1, a system 20 is illustrated in which rotational vibration is suppressed, according to an embodiment of the present invention. System 20 comprises an electronic device, such as a computer-based device 22, e.g. a high performance storage array product. Within computer-based device 22, there may be components with rotating members that establish rotational vibration through system 20.

For example, computer-based device 22 may comprise at least one drive module 24, e.g. a disk drive module. In the specific embodiment illustrated, a plurality of disk drive modules 24 are mounted within a chassis 26 of device 22, e.g. a storage array chassis. Each of the disk drive modules 24 is capable of establishing rotational vibration that is controlled within system 20.

An embodiment of an individual disk drive module 24 is illustrated in FIG. 2. In this embodiment, disk drive module 24 comprises a disk drive 27 mounted within a carrier 28. By way of example, disk drive 27 may be affixed within carrier 28. In the embodiment illustrated, a plurality of fasteners 30 affix disk drive 27 and carrier 28. Fasteners 30 may comprise screws that extend through corresponding openings 32 (see FIG. 3) in carrier 28 for threaded engagement with disk drive 27. It should be noted that disk drive 27 is an example of one type of device that produces rotational vibration, but there may be a wide variety of other types of drives or devices that induce rotational vibration into the system. However, such other devices also can benefit from combination with a carrier, such as carrier 28, disposed within a chassis in a manner that suppresses the effects of rotational vibration, as described below.

Carrier 28 may have various configurations depending on the specific environment and application in which it is utilized. However, the illustrated carrier 28 comprises an outer carrier housing 34 having a first guide rail 36 and a second guide rail 38. Guide rails 36 and 38 are disposed generally parallel to one another and are linked together by a structural cross member 40, as illustrated best in FIG. 3.

Housing 34 also may comprise additional enclosure components, such as cover member 42. In the embodiment illustrated, cover member 42 has a ventilated portion 44 that extends between guide rails 36 and 38. Additionally, cover member 42 may comprise side panels 46 that each extend generally at a right angle with respect to ventilated portion 44. Side panels 46 are spaced to lie adjacent the inside surface of guide rails 36 and 38. When carrier 28 is coupled to disk drive 27, fasteners 30 may be inserted through openings 32 formed in guide rails 36, 38 and through side panels 46 to simultaneously secure guide rails 36, 38 and cover member 42 to disk drive 27.

Additionally, carrier 28 may comprise a bezel assembly 48. Bezel assembly 38 is disposed across the front of drive module 24 and may be secured to structural cross member 40 by a plurality of fasteners 50, such as screws, that extend through corresponding openings 52 in cross member 40 for threaded engagement with bezel assembly 48 (see FIG. 3).

Bezel assembly 48 may have a variety of configurations and components. However, in the example illustrated, bezel assembly 48 comprises a base portion 54 to which a handle assembly 56 is pivotably attached via a pivot 58. Handle assembly 56 comprises a handle 60 and a latch portion 62 having at least one protruding engagement feature 64. When handle 60 is moved to a closed position, as illustrated in FIGS. 1 and 2, engagement features 64 extend outwardly to prevent inadvertent removal of the drive module 24 from surrounding chassis 26, such as a storage enclosure disk bay chassis. However, when handle 60 is pulled outwardly to create a pivoting motion about pivot 58, engagement features 64 are pivoted inwardly to a position where interference with surrounding chassis 26 is no longer created. When handle assembly 56 is in this disengaged position, the drive module 24 may be removed from its surrounding chassis 26.

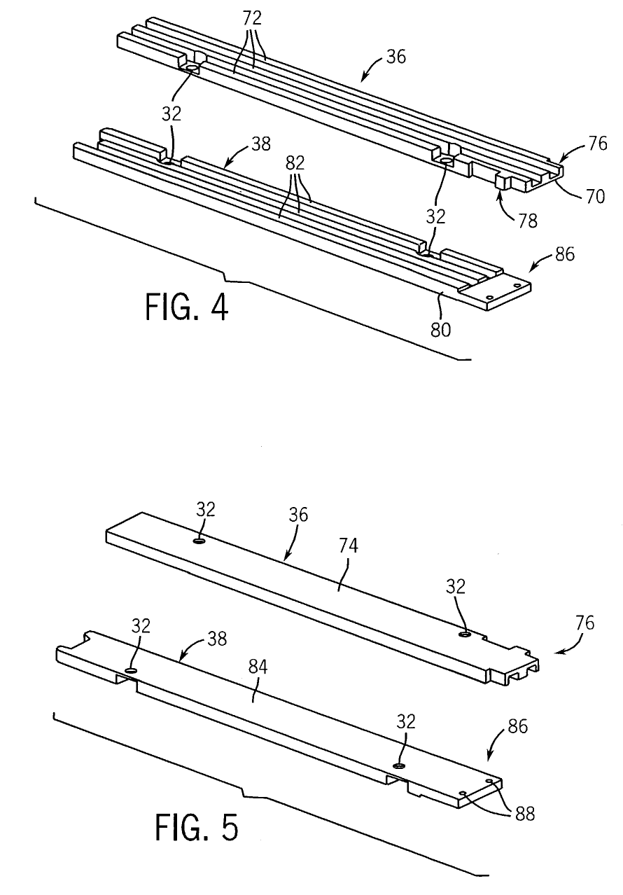

Guide rails 36 and 38 are designed to facilitate control, e.g. suppression, of rotational vibration. An embodiment of guide rails 36 and 38 is illustrated in FIGS. 4 and 5. However, regardless of the specific configuration of the guide rail embodiment, the guide rails are formed from a material having a high stiffness to weight characteristic that is stronger than engineering glass-filled plastic resins and may be at least five times stronger than such engineering glass-filled plastic resins.

An exemplary material is a magnesium material which has a high stiffness to weight property. Depending on the specific formulation of the magnesium material, the magnesium guide rails can be at least five times stronger than engineering glass-filled plastic resins without adding excessive weight. In fact, magnesium materials may be, for example, one-third lighter than aluminum. Although a variety of magnesium materials can be utilized, one example is a general grade magnesium alloy known as AZ91.

Magnesium has an inherent vibration damping characteristic and a superior strength to weight ratio that can be used to control rotational vibration without detrimental carrier weight increases. The magnesium rails 36 and 38 serve as an interface between the source of vibration, e.g. the disk drive, and the enclosure chassis, such as chassis 26. The stiffness of the mounting structure, e.g. carrier 28, and specifically the stiffness added to the system via magnesium guide rails 36 and 38 reduces the displacement and amplification of vibration energies due to the higher natural resonant frequency of the system. Rotational vibration energy from the disk drive is converted through viscoelastic internal friction to negligible heat. Thus, the stiffness of magnesium coupled with the passive, vibration damping properties of magnesium is highly effective in controlling rotational vibration.

In the embodiment illustrated in FIGS. 4 and 5, guide rail 36 is formed as an elongate panel 70 having a plurality of longitudinal ribs 72 extending outwardly on an exterior side of guide rail 36 (see FIG. 4). On an opposite side of elongate panel 70, an internal surface 74 is designed to abut against a corresponding side panel 46 of cover member 42 when guide rail 36 is affixed to disk drive 27 via fasteners 30 inserted through openings 32 in elongate panel 70 (see FIG. 5). Guide rail 36 also comprises an attachment end 76 designed for connection to structural cross member 40. The configuration of attachment end 76 may comprise suitable retention features 78 designed to engage or interlock with cross member 40. However, attachment end 76 also may be connected to cross member 40 by other suitable mechanisms, such as fasteners that may include screws, clips, adhesives and other fasteners.

Guide rail 38 is similarly designed with an elongate panel 80 having a plurality of longitudinal ribs extending from an external surface. On an opposite side of elongate panel 80, guide rail 38 comprises a surface 84 that is designed for abutting engagement with the corresponding side panel 46 of cover member 42 when guide rail 38 is affixed to disk drive 27. As described above with respect to guide rail 36, guide rail 38 and cover 42 may be affixed to disk drive 27 by fasteners 30 that are disposed through the appropriate openings 32 and threadably engaged with disk drive 27 (see FIG. 5). Guide rail 38 also comprises an attachment end 86 by which the guide rail is engaged with structural cross member 40 at an end generally opposite guide rail 36. Attachment end 86 may comprise a variety of retention features 88, such as openings to receive appropriate threaded fasteners therethrough for threaded engagement with structural cross member 40. Other retention features may comprise a variety of interlocking features, adhesives, clips, and other fastening mechanisms.

Longitudinal ribs 72 and 82 can be used to facilitate the insertion and retraction of modules 24 from the enclosure chassis 26. For example, the guide rails may be formed for sliding engagement with corresponding rails or features (not shown) of chassis 26. Additionally, longitudinal ribs 72 and 82 provide even greater rigidity to carrier 28. The added stiffness further reduces the displacement and amplification of vibration energies due to the higher natural resonant frequency of the system.

Due to the heat conductivity of magnesium, at least one of guide rails 36 and 38 may be used to conduct heat away from a heat generating component, such as disk drive 27. The heat conductivity of magnesium is much higher than, for example, injection molded plastic and facilitates use of the chassis 26 as a heat sink for greater heat dissipation. Thus, components, such as disk drive 27, can be cooled more effectively.

The added cooling reduces reliance on other cooling systems, such as forced air cooling from system fans used to draw heat away from the disk drives. Thus, by deploying at least one of the guide rails 36 and 38 in proximity to the heat generating device, and particularly when secured to the heat generating device via a thermally conductive path, the transfer of heat away from the heat generating component is facilitated. The overall system 20 benefits from the greater heat transfer capability through reduced fan noise, increased system reliability, tighter disk packing density and greater carrier robustness.

By forming guide rails 36 and 38 as panels of magnesium, electrical properties of the overall system also may be improved. The electrical conductivity of magnesium allows the magnesium guide rails to be used as a ground between a low impedance disk module, e.g. disk drive 27, and a surrounding chassis, e.g. chassis 26. Thus, by affixing at least one of the guide rails to the corresponding disk drive 27 and surrounding chassis 26 via conductive paths, the guide rail can be used as an electrical pathway for grounding the disk drive. Additionally, the magnesium panels 70 and 80 serve as an electromagnetic interference (EMI) and radio frequency interference (RFI) shield. Thus, system reliability and performance can be enhanced by providing an EMI/RFI shield around at least a portion of the disk drive 27.

Although guide rails 36 and 38 may be made by variety of methods and in a variety of configurations, one suitable process for forming the guide rails is thixotropic metal injection molding. Thixotropic metal molding utilizes a combination of plastic molding and casting technology. This approach facilitates the molding of magnesium alloys into near net shape parts with minimum additional machining. It also allows the formation of more highly complex intricate designs at a lower cost than many other types of fabrication.

While the subject matter described herein may be susceptible to various modifications and alternative forms, specific embodiments have been illustrated and described by way of example. However, it should be understood that the subject matter is not intended to be limited to the particular forms disclosed. Rather, the subject matter is to cover modifications, equivalents and alternatives falling within the spirit and scope of the subject matter as defined by the following appended claims.

What is claimed is:

1. A disk drive system, comprising:
a disk drive; and
a carrier in which the disk drive is affixed, the carrier having a structural member comprising magnesium to stiffen the carrier and control rotational vibration.

2. The disk drive as recited in claim 1, wherein the structural member comprises a pair of guide rails.

3. The disk drive as recited in claim 2, wherein the carrier further comprises a cover extending between the pair of guide rails.

4. The disk drive as recited in claim 3, wherein the carrier further comprises a bezel assembly.

5. The disk drive as recited in claim 1, wherein the structural member is disposed to conduct heat away from the disk drive.

6. The disk drive as recited in claim 1, wherein the structural member is disposed to provide a low impedance ground for the disk drive.

7. The disk drive as recited in claim 1, wherein the structural member is positioned to provide an Electromagnetic Interference (EMI) and Radio Frequency Interference (RFI) shield.

8. A system for controlling rotation vibration, comprising:
a device chassis;
a plurality of disk drive modules, each disk drive module being mounted in the device chassis by a pair of guide rails formed of a magnesium material.

9. The system as recited in claim 8, wherein the device chassis comprises a storage array chassis.

10. The system as recited in claim 8, wherein each disk drive module comprises a disk drive mounted in a carrier.

11. The system as recited in claim 10, wherein the carrier comprises a cover extending between the pair of guide rails.

12. The system as recited in claim 10, wherein the carrier comprises a bezel assembly having a handle.

13. The system as recited in claim 8, wherein each guide rail of the pair of guide rails comprises a plurality of longitudinal ribs.

14. The system as recited in claim 10, wherein the pair of guide rails conduct heat from the disk drive.

15. The system as recited in claim 14, wherein the pair of guide rails are positioned to shield the disk drive from EMI and RFI.

16. A method for reducing rotational vibration associated with a disk drive, comprising:
forming a pair of structural members from a magnesium based material;
attaching the pair of structural members to a drive; and
mounting the drive in a chassis.

17. The method as recited in claim 16, wherein forming comprises forming a pair of guide rails.

18. The method as recited in claim 17, wherein forming a pair of guide rails comprises creating longitudinal ribs along each guide rail.

19. The method as recited in claim 17, wherein attaching comprises using a plurality of threaded fasteners to secure the pair of guide rails to the drive.

20. The method as recited in claim 16, further comprising positioning the pair of structural members to conduct heat away from the drive.

21. The method as recited in claim 16, further comprising positioning the pair of structural members to shield the drive from EMI and RFI.

22. The method as recited in claim 16, further comprising grounding the drive to the chassis through at least one of the pair of structural members.

23. A system for reducing rotational vibration associated with a disk drive, comprising:
means for forming a drive carrier with a high stiffness to weight ratio using magnesium; and
means for mounting a drive within the driver carrier.

24. The system as recited in claim 23, wherein the means for forming comprises a pair of magnesium guide rails.

25. The system as recited in claim 23, wherein the means for mounting comprises a plurality of screws.
